(19) United States
(12) Patent Application Publication
(10) Pub. No.: US 2026/0251929 A1
(43) Pub. Date: Aug. 27, 2026

(54) ELECTRONIC DEVICE

(71) Applicant: InnoLux Corporation, Miao-Li County (TW)

(72) Inventors: Yu-Chen HUANG, Miao-Li County (TW); Ting-Wei LIANG, Miao-Li County (TW); Jiunn-Shyong LIN, Miao-Li County (TW); I-An YAO, Miao-Li County (TW); Mei-Chi HSU, Miao-Li County (TW)

(21) Appl. No.: 19/463,921

(22) Filed: Jan. 29, 2026

(30) Foreign Application Priority Data
Feb. 24, 2025 (CN) 202510203562.4

(51) Int. Cl. G02F 1/133; H10K 39/00; H10K 39/10

(52) U.S. Cl. CPC G02F 1/13324; H10K 39/10; H10K 39/401

(57) ABSTRACT

An electronic device includes: a first reflective panel having a first display side and including a first display layer; a second reflective panel having a second display side and including a second display layer; and a photoelectric conversion unit disposed between the first display layer and the second display layer, wherein the photoelectric conversion unit is used to receive external light and convert the external light into electrical energy to provide the electrical energy to the first reflective panel and the second reflective panel, wherein the first display side and the second display side face different directions respectively.

### CROSS-REFERENCE TO RELATED APPLICATIONS

This application claims the benefits of the Chinese Patent Application Serial Number 202510203562.4, filed on Feb. 24, 2025, the subject matter of which is incorporated herein by reference.

### BACKGROUND

### Field

The present disclosure relates to an electronic device, and more specifically, to a double-sided display electronic device comprising a photoelectric conversion unit.

### Description of Related Art

Reflective electronic (display) devices are widely used in our daily lives. If a bi-stable cholesteric liquid crystal panel is used, its power consumption can be greatly reduced, which is beneficial to the environment.

However, there are still some parts that need improvement in current electronic devices, such as how to effectively achieve energy conservation. Therefore, continued research and development of improved electronic devices is still necessary.

### SUMMARY

The present disclosure provides an electronic device, comprising: a first reflective panel having a first display side and comprising a first display layer; a second reflective panel having a second display side and comprising a second display layer; and a photoelectric conversion unit disposed between the first display layer and the second display layer, wherein the photoelectric conversion unit is used to receive external light and convert the external light into electrical energy to provide the electrical energy to the first reflective panel and the second reflective panel, wherein the first display side and the second display side face different directions respectively.

Other novel features of the disclosure will become more apparent from the following detailed description when taken in conjunction with the accompanying drawings.

### BRIEF DESCRIPTION OF DRAWINGS

FIG. 1A is a schematic view of an electronic device according to one embodiment of the present disclosure.

FIG. 1B is a schematic view of an electronic device according to one embodiment of the present disclosure.

FIG. 2A is a schematic view of an electronic device according to one embodiment of the present disclosure.

FIG. 2B is a schematic view of an electronic device according to one embodiment of the present disclosure.

FIG. 3 is a schematic view of an electronic device according to one embodiment of the present disclosure.

FIG. 4 is a schematic view of an electronic device according to one embodiment of the present disclosure.

FIG. 5 is a schematic view of an electronic device according to one embodiment of the present disclosure.

FIG. 6 is a schematic view of an electronic device according to one embodiment of the present disclosure.

FIG. 7A is a top schematic view of a part of an electronic device according to one embodiment of the present disclosure.

FIG. 7B is a cross-sectional schematic view of an electronic device according to one embodiment of the present disclosure.

FIG. 8 is a schematic view of an electronic device according to one embodiment of the present disclosure.

FIG. 9 is a cross-sectional schematic view of a part of an electronic device according to one embodiment of the present disclosure.

FIG. 10 is a cross-sectional schematic view of a part of an electronic device according to one embodiment of the present disclosure.

### DETAILED DESCRIPTION

The following is a detailed description of the electronic device according to the embodiment of the present disclosure. It should be understood that the following description provides many different embodiments for implementing different aspects of some embodiments of the present disclosure. Specific examples of each component and its configuration are described below to simplify the embodiments of the present disclosure. Of course, these are only examples and are not intended to limit the present disclosure. In addition, similar and/or corresponding reference numerals may be used to identify similar and/or corresponding elements in different embodiments to clearly describe the present disclosure. However, the use of these similar and/or corresponding reference numerals is only for the purpose of simply and clearly describing some embodiments of the present disclosure, and does not imply any correlation between the different embodiments and/or structures discussed.

The embodiments of the present disclosure may be understood in conjunction with the drawings, which are also considered part of the disclosure. It should be understood that the drawings of the present disclosure are not drawn to scale, and in fact, the size of the elements may be arbitrarily enlarged or reduced in order to clearly show the features of the present disclosure. In addition, the directional terms mentioned in the present disclosure, such as “up”, “down”, “front”, “back”, “left”, “right”, etc., are only referenced to the directions of the accompanying drawings. Therefore, the directional terms used are for illustration and are not intended to limit the present disclosure. In the accompanying drawings, each diagram depicts the general characteristics of the methods, structures and/or materials used in a particular embodiment. However, these diagrams should not be interpreted as defining or limiting the scope or nature covered by these embodiments. For example, for the sake of clarity, the relative size, thickness and position of each layer, region and/or structure may be reduced or enlarged.

One structure (or layer, component, or substrate) described in the present disclosure is located on/above another structure (or layer, component, or substrate). This may mean that the two structures are adjacent and directly connected, or the two structures are adjacent rather than directly connected. Indirect connection means that there is at least one intermediary structure (or intermediary layer, intermediary component, intermediary substrate, or intermediary spacer) between two structures. The lower surface of one structure is adjacent to or directly connected to the upper surface of the intermediary structure, and the upper surface of another structure is adjacent to or directly connected to the lower surface of the intermediary structure. The intermediary structure can be composed of a single-layer or multi-layer solid structure or a non-solid structure, and there is no limit. In the present disclosure, when a structure is disposed “on” another structure, it may mean that the structure is “directly” on the other structure, or that the structure is “indirectly” on the other structure, that is, at least one structure is also sandwiched between the structure and the other structure. In the present disclosure, the term “relatively disposed” or “disposed relative to” refers to, for example, the elements substantially overlapping each other, but the present disclosure is not limited thereto.

In addition, it should be understood that the ordinal numbers used in the description and the claims, such as “first”, “second”, etc., are intended only to describe the elements claimed and imply or represent neither that the (these) elements have any proceeding ordinals, nor that sequence between one claimed element and another claimed element or between steps of a manufacturing method. The use of these ordinals is merely to differentiate one claimed element having a certain designation from another claimed element having the same designation. The same words may not be used in the claim and the description. For example, the first element in the description may be the second element in the claim.

In some embodiments of the present disclosure, terms related to joining and connecting, such as “connection”, “interconnection”, etc., unless otherwise defined, may mean that two structures are in direct contact, or may also mean that two structures are not in direct contact where other structures are located between these two structures. The terms “joint” and “connection” can also include situations where both structures are movable, or where both structures are fixed. In addition, the term “electrically connected” or “coupled” includes any direct and indirect electrical connection means.

In the present specification, the terms, such as “about”, “substantially”, or “approximately”, are generally interpreted as within 10%, 5%, 3%, 2%, 1%, or 0.5% of a given value or range. Unless otherwise stated, when a value is “in a range from a first value to a second value” or “in a range between a first value and a second value”, the value can be the first value, the second value, or another value between the first value and the second value. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°. In the present disclosure, the term “the given range is from the first value to the second value” and “the given range falls within the range of the first value to the second value” mean that the given range includes the first value, the second value and another value between the first value and the second value.

Furthermore, according to some embodiments of the present disclosure, the thickness, the length, the width, or the distance and angle between elements may be measured by using an optical microscope (OM), scanning electron microscope (SEM), film thickness profiler (α-step), ellipsometer, or other suitable methods. More specifically, according to some embodiments, a scanning electron microscope can be used to obtain a cross-sectional image of the structure and measure the thickness, length, width of each element or the distance and angle between elements.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

It should be noted that the following embodiments may be implemented by replacing, reorganizing, or mixing features of several different embodiments without departing from the spirit of the present disclosure to implement other embodiments. The features of the various embodiments may be mixed and matched as desired as long as they do not violate the spirit of the invention or conflict with each other.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those known in the art, the background of the present disclosure or the context of the present specification, and should not be read by an ideal or over-formal way.

The electronic device of the present disclosure may include electronic components, and the electronic components can include passive components, active components or a combination thereof, such as capacitors, resistors, inductors, varactor diodes, variable capacitors, filters, diodes, transistors, sensors, microelectromechanical system components (MEMS), liquid crystal chips, etc., but the present disclosure is not limited thereto. The diode may include light emitting diode or non-light emitting diode. The diode includes a P-N junction diode, a PIN diode or a constant current diode. The light emitting diode may include, for example, an organic light emitting diode (OLED), a mini LED, a micro LED, a quantum dot LED, fluorescence, phosphors, other suitable material or a combination thereof, but the present disclosure is not limited thereto. The sensor may include, for example, a capacitive sensor, an optical sensor, an electromagnetic sensor, a fingerprint sensor (FPS), a touch sensor, an antenna or a pen sensor, but the present disclosure is not limited thereto. The following will be a display device as an electronic device to illustrate the present disclosure, but the present disclosure is not limited thereto.

It should be noted that the following embodiments may be implemented by replacing, reorganizing, or mixing features of several different embodiments without departing from the spirit of the present disclosure to implement other embodiments. The features of the various embodiments may be mixed and matched as desired as long as they do not violate the spirit of the invention or conflict with each other. It should be noted that the technical solutions provided in the following different embodiments can be replaced, combined or mixed with each other to form another embodiment without violating the spirit of the present disclosure.

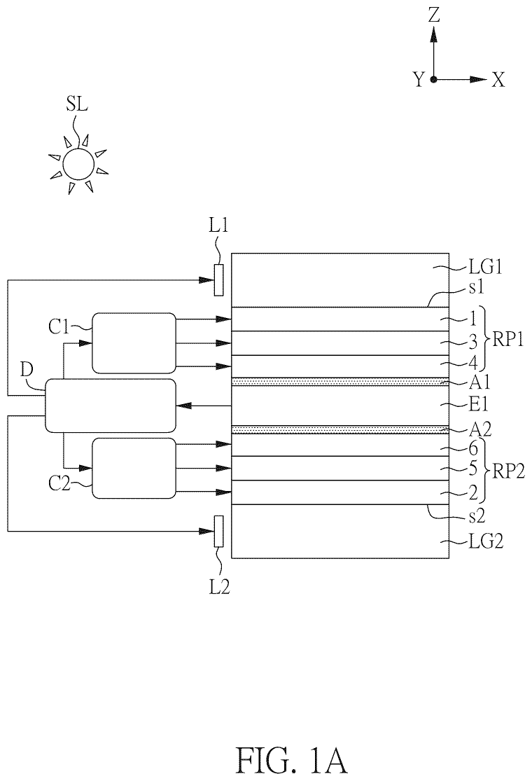

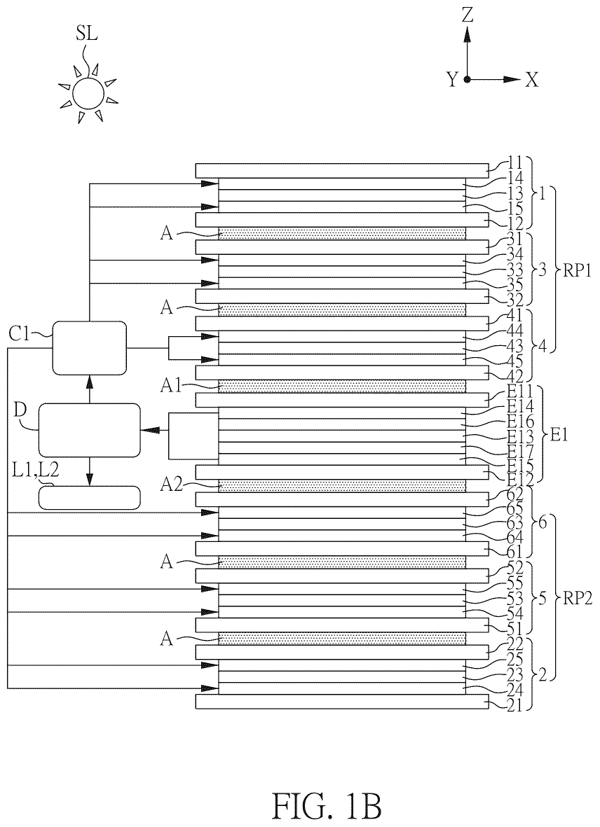

FIG. 1A is a schematic view of an electronic device according to one embodiment of the present disclosure. FIG. 1B is a schematic view of an electronic device according to one embodiment of the present disclosure. FIG. 1A is similar to FIG. 1B, and FIG. 1B shows a detailed structure of a part of the electronic device. In addition, for convenience of explanation, some components are selectively omitted in the figures.

In one embodiment of the present disclosure, as shown in FIG. 1A or FIG. 1B, the electronic device may comprise: a first reflective panel RP1 having a first display side s1 and comprising a first display layer 13; a second reflective panel RP2 having a second display side s2 and comprising a second display layer 23; and a photoelectric conversion unit E1 disposed between the first display layer 13 and the second display layer 23, wherein the photoelectric conversion unit E1 is used to receive external light SL and covert the external light SL into electrical energy to provide the electrical energy to the first reflective panel RP1 and the second reflective panel RP2; wherein the first display side s1 and the second display side s2 face different directions respectively.

More specifically, as shown in FIG. 1A or FIG. 1B, the first reflective panel RP1 may comprise a first panel 1, a third panel 3 and a fourth panel 4 arranged opposite to each other, and the third panel 3 is disposed between the first panel 1 and the fourth panel 4. As shown in FIG. 1B, the first panel 1 may comprise: a first substrate 11; a second substrate 12 disposed opposite to the first substrate 11; a first display layer 13 disposed between the first substrate 11 and the second substrate 12; a first electrode layer 14 disposed between the first substrate 11 and the first display layer 13; and a second electrode layer 15 disposed between the second substrate 12 and the first display layer 13. The third panel 3 may comprise: a fifth substrate 31; a sixth substrate 32 disposed opposite to the fifth substrate 31; a third display layer 33 disposed between the fifth substrate 31 and the sixth substrate 32; a fifth electrode layer 34 disposed between the fifth substrate 31 and the third display layer 33; and a sixth electrode layer 35 disposed between the sixth substrate 32 and the third display layer 33. The fourth panel 4 may comprise: a seventh substrate 41; an eighth substrate 42 disposed opposite to the seventh substrate 41; a fourth display layer 43 disposed between the seventh substrate 41 and the eighth substrate 42; a seventh electrode layer 44 disposed between the seventh substrate 41 and the fourth display layer 43; and an eighth electrode layer 45 disposed between the eighth substrate 42 and the fourth display layer 43. For example, when the first display layer 13, the third display layer 33 and the fourth display layer 43 comprise cholesteric liquid crystals, voltage may be applied to the first electrode layer 14 and the second electrode layer 15 respectively to generate an electric field to control the first display layer 13; voltage may be applied to the fifth electrode layer 34 and the sixth electrode layer 35 respectively to generate an electric field to control the third display layer 33; and voltage may be applied to the seventh electrode layer 44 and the eighth electrode layer 45 respectively to generate an electric field to control the fourth display layer 43. Thus, each the first display layer 13, the third display layer 33 and the fourth display layer 43 can be in different states, for example, switching between the transmissive state (or scattering state) and the reflective state, so the first reflective panel RP1 can display images. More specifically, when the first display layer 13, the third display layer 33 and the fourth display layer 43 are switched to the transmissive state (or the scattering state), at least part of incident light may pass through the first reflective panel RP1 to the photoelectric conversion unit E1, the photoelectric conversion unit E1 may absorb at least part of the incident light and the first reflective panel RP1 approximately displays a dark state. When the first display layer 13, the third display layer 33 and/or the fourth display layer 43 are selectively switched to the reflective state, at least part of the incident light may be reflected by the first display layer 13, the third display layer 33 and/or the fourth display layer 43, and the first reflective panel RP1 can display images.

The second reflective panel RP2 may comprise a second panel 2, a fifth panel 5 and a sixth panel 6 arranged opposite to each other, wherein the fifth panel 5 is disposed between the second panel 2 and the sixth panel 6. The second panel 2 may comprise: a third substrate 21; a fourth substrate 22 disposed opposite to the third substrate 21; a second display layer 23 disposed between the third substrate 21 and the fourth substrate 22; a third electrode layer 24 disposed between the third substrate 21 and the second display layer 23; and a fourth electrode layer 25 disposed between the fourth substrate 22 and the second display layer 23. The fifth panel 5 may comprise: a ninth substrate 51; a tenth substrate 52 disposed opposite to the ninth substrate 51; a fifth display layer 53 disposed between the ninth substrate 51 and the tenth substrate 52; a ninth electrode layer 54 disposed between the ninth substrate 51 and the fifth display layer 53; and a tenth electrode layer 55 disposed between the tenth substrate 52 and the fifth display layer 53. The sixth panel 6 may comprise: a eleventh substrate 61; a twelfth substrate 62 disposed opposite to the eleventh substrate 61; a sixth display layer 63 disposed between the eleventh substrate 61 and the twelfth substrate 62; an eleventh electrode layer 64 disposed between the eleventh substrate 61 and the sixth display layer 63; and a twelfth electrode layer 65 disposed between the twelfth substrate 62 and the sixth display layer 63. For example, when second display layer 23, the fifth display layer 53 and the sixth display layer 63 comprise cholesteric liquid crystals, voltage may be applied to the third electrode layer 24 and the fourth electrode layer 25 respectively to generate an electric field to control the second display layer 23; voltage may be applied to the ninth electrode layer 54 and the tenth electrode layer 55 respectively to generate an electric field to control the fifth display layer 53; and voltage may be applied to the eleventh electrode layer 64 and the twelfth electrode layer 65 to generate an electric field to control the sixth display layer 63. Thus, each the second display layer 23, the fifth display layer 53 and the sixth display layer 63 can be in different states, for example, switching between the transmissive state (or the scattering state) and the reflective state, so the second reflective panel RP2 can display images. More specifically, when the second display layer 23, the fifth display layer 53 and the sixth display layer 63 are switched to the transmissive state (or the scattering state), at least part of incident light may pass through the second reflective panel RP2 to the photoelectric conversion unit E1, the photoelectric conversion unit E1 may absorb at least part of the incident light and the second reflective panel RP2 approximately displays a dark state. When the second display layer 23, the fifth display layer 53 and/or the sixth display layer 63 are selectively switched to the reflective state, at least part of the incident light may be reflected by the second display layer 23, the fifth display layer 53 and/or the sixth display layer 63, and the second reflective panel RP2 can display images.

As shown in FIG. 1A or FIG. 1B, the first display side s1 of the first reflective panel RP1 may be a side of the first panel 1 away from the second reflective panel RP2 and, for example, may be a side of the first substrate 11 away from the second panel 2. The second display side s2 of the second reflective panel RP2 may be a side of the second panel 2 away from the first reflective panel RP1 and, for example, may be a side of the third substrate 21 away from the first panel 1. In other words, the first display side s1 of the first reflective panel RP1 and the second display side s2 of the second reflective panel RP2 are located on two sides of the photoelectric conversion unit E1. When the display direction of the first reflective panel RP1 is different from the display direction of the second reflective panel RP2, the double-sided display of the electronic device can be realized.

In the present disclosure, the materials of the first substrate 11, the second substrate 12, the third substrate 21, the fourth substrate 22, the fifth substrate 31, the sixth substrate 32, the seventh substrate 41, the eighth substrate 42, the ninth substrate 51, the tenth substrate 52, the eleventh substrate 61 and the twelfth substrate 62 may respectively comprise a rigid substrate or a flexible substrate, for example, comprising glass, quartz, sapphire, ceramics, plastics, polycarbonate (PC), polyimide (PI), polypropylene (PP), polyethylene terephthalate (PET), polymethylmethacrylate (PMMA), other suitable materials or a combination thereof, but the present disclosure is not limited thereto. The materials of the first electrode layer 14, the second electrode layer 15, the third electrode layer 24, the fourth electrode layer 25, the fifth electrode layer 34, the sixth electrode layer 35, the seventh electrode layer 44, the eighth electrode layer 45, the ninth electrode layer 54, the tenth electrode layer 55, the eleventh electrode layer 64 and the twelfth electrode layer 65 may respectively comprise a transparent conductive material, such as indium zinc oxide (IZO), indium tin oxide (ITO), indium tin zinc oxide (ITZO), indium gallium zinc oxide (IGZO), aluminum zinc oxide (AZO), or a combination thereof, but the present disclosure is not limited thereto.

In one embodiment of the present disclosure, the first display layer 13, the second display layer 23, the third display layer 33, the fourth display layer 43, the fifth display layer 53 and the sixth display layer 63 may respectively comprise cholesteric liquid crystals. For example, the first display layer 13 and the second display layer 23 may comprise cholesteric liquid crystals reflecting blue light in the planar state, the third display layer 33 and the fifth display layer 53 may comprise cholesteric liquid crystals reflecting green light in the planar state, the fourth display layer 43 and the sixth display layer 63 may comprise cholesteric liquid crystals reflecting red light in the planar state, but the present disclosure is not limited thereto, and the aforesaid display layers may reflect light with different colors according to the designs. When the first display layer 13, the second display layer 23, the third display layer 33, the fourth display layer 43, the fifth display layer 53 and the sixth display layer 63 meet the aforesaid design, the reflection efficiency of incident light can be increased, thereby improving the display quality of the electronic device, or enabling the color display of the electronic device. In another embodiment of the present disclosure, the first reflective panel RP1 may selectively omit one or two of the first panel 1, the third panel 3 and fourth panel 4, and the second reflective panel RP2 may selectively omit one or two of the second panel 2, the fifth panel 5 and the sixth panel 6. Thus, the electronic device can selectively be a monochrome display panel or a two-color mixed display device.

In one embodiment of the present disclosure, as shown in FIG. 1A and FIG. 1B, the photoelectric conversion unit E1 may be disposed between the first reflective panel RP1 and the second reflective panel RP2. The photoelectric conversion unit E1 may comprise: a thirteenth substrate E11; a fourteenth substrate E12 disposed opposite to the thirteenth substrate E11; a photoelectric conversion layer E13 disposed between the thirteenth substrate E11 and the fourteenth substrate E12; a thirteenth electrode layer E14 disposed between the thirteenth substrate E11 and the photoelectric conversion layer E13; a fourteenth electrode layer E15 disposed between the fourteenth substrate E12 and the photoelectric conversion layer E13; a hole transport layer E16 disposed between the thirteenth electrode layer E14 and the photoelectric conversion layer E13; and an electron transport layer E17 disposed between the fourteenth electrode layer E15 and the photoelectric conversion layer E13. In the present disclosure, the photoelectric conversion unit E1 may be, for example, a perovskite solar cell or other suitable cells. Perovskite solar cells can have advantages such as adjustable absorption wavelength, good light absorption, good light transmittance and/or high photoelectric conversion efficiency, which can improve the photoelectric conversion effect of electronic devices and achieve power saving, but the present disclosure is not limited thereto. Thus, the photoelectric conversion unit E1 shown in FIG. 1B may be a perovskite solar cell with an n-i-p structure. In other embodiments, even not shown in the figures, the positions of the hole transport layer E16 and the electron transport layer E17 may be changed, so the photoelectric conversion unit E1 may be a perovskite solar cell with a p-i-n structure, but the present disclosure is not limited thereto. In the present disclosure, the photoelectric conversion unit E1 in the electronic device can absorb at least part of the incident light that is not reflected by the display layer and converts it into electrical energy to be supplied to the first reflective panel RP1 and/or the second reflective panel RP2, thereby saving power or improving the color purity of the reflected light. In the present disclosure, the photoelectric conversion unit E1 may respectively absorb light passing through the first reflective panel RP1 and/or the second reflective panel RP2, thereby improving the utilization of light. In one embodiment of the present disclosure, even not shown in the figure, the thirteenth substrate E11 and/or the fourteenth substrate E12 of the photoelectric conversion unit E1 may be selectively omitted, that is, the thirteenth electrode layer E14 may be directly disposed on the eighth substrate 42 of the fourth panel 4, and/or the fourteenth electrode layer E15 may be directly disposed on the twelfth substrate 62 of the sixth panel 6, thereby decreasing the thickness of the electronic device.

In the present disclosure, the materials of the thirteenth substrate E11 and the fourteenth substrate E12 may be similar to that of the first substrate 11 respectively, which are not described again here. The materials of the thirteenth electrode layer E14 and the fourteenth electrode layer E15 may respectively comprise a transparent conductive material or a semi-transparent conductive material, such as fluorine-doped tin oxide (FTO), indium tin oxide (ITO), aluminum zinc oxide (AZO), indium zinc oxide (IZO) or a combination thereof, but the present disclosure is not limited thereto. The photoelectric conversion layer E13 may comprise perovskite with formula, ABX₃, wherein A may be, for example, methylamine, ethylamine, formamidine, cesium (Cs) or rubidium (Rb), B may be, for example, lead, tin, titanium or germanium, X may be, for example, halogen or oxygen, but the present disclosure is not limited thereto. The photoelectric conversion layer E13 may comprise any suitable material. The material of the hole transport layer E16 may comprise poly(3,4-ethylenedioxythiophene): polystyrene sulfonate (PEDOT: PSS), nickel oxide, molybdenum oxide, tungsten oxide, vanadium oxide, 2, 2′, 7, 7′-tetrakis[N, N-di(4-methoxyphenyl)amino]-9, 9′-spirobifluorene (spiro-OMeTAD), N, N′-bis(3-methylphenyl)-N, N′-diphenyl-[1, 1′-biphenyl]-4, 4′-diamine (TPD), N, N′-diphenyl-N, N′-bis(4-methylphenyl)-4, 4′-diphenylenediamine (PTPD), poly(3-hexylthiophene-2,5-diyl (P3HT) or a combination thereof, but the present disclosure is not limited thereto. The material of the electron transport layer E17 may comprise calcium, lithium fluoride, cesium carbonate, titanium oxide, zinc oxide, zirconium oxide, 2,9-methyl-4,7-diphenyl-1,10-phenanthenoline (bathocuproine, BCP), poly[(9,9-bis(3′-(N, N-dimethylamino)propyl)-2,7-fluorene)-alt-2,7-(9,9-dioctylfluorene)] (PFN), fullerene derivatives or a combination thereof, but the present disclosure is not limited thereto. In the present disclosure, even not shown in the figure, the photoelectric conversion unit E1 may selectively comprise other material layers, such as a hole-blocking layer, an electron-blocking layer, a hole-injection layer, an electron-injection layer and/or a combination thereof, thereby improving the power conversion efficiency or stability of the photoelectric conversion unit E1.

In one embodiment of the present disclosure, as shown in FIG. 1A, the electronic device may further comprise an energy storage device D electrically connected to the photoelectric conversion unit E1. The photoelectric conversion unit E1 can convert the absorbed light into electrical energy, and the electrical energy can be stored in the energy storage device D. The electronic device may further comprise a first driving circuit C1 and a second driving circuit C2, the first driving circuit C1 may be electrically connected to the energy storage device D, the first panel 1, the third panel 3 and the fourth panel 4 respectively, the second driving circuit C2 may be electrically connected to the energy storage device D, the second panel 2, the fifth panel 5 and the sixth panel 6 respectively. The first driving circuit C1 and the second driving circuit C2 may respectively receive the electrical energy provided by the energy storage device D, and respectively provide the electrical energy to each panel correspondingly electrically connected, thereby driving each panel correspondingly, so the first reflective panel RP1 and the second reflective panel RP2 can respectively display images, but the present disclosure is not limited thereto. The first driving circuit C1 and the second driving circuit C2 may, for example, comprise a driver IC, a driving circuit board and/or a control board. The first driving circuit C1 may comprise, for example, a driver IC or a driving circuit board that provides different signals, such as scan or data signals, but the present disclosure is not limited thereto.

In one embodiment of the present disclosure, as shown in FIG. 1B, the electronic device may further comprise an energy storage device D electrically connected to the photoelectric conversion unit E1. The photoelectric conversion unit E1 can convert the absorbed light into electrical energy, and the electrical energy can be stored in the energy storage device D. The electronic device may further comprise a first driving circuit C1, the first driving circuit C1 may be electrically connected to the electrode layers in each panels (for example, the first electrode layer 14 and the second electrode layer 15 of the first panel 1, the third electrode layer 24 and the fourth electrode layer 25 of the second panel 2, the fifth electrode layer 34 and the sixth electrode layer 35 of the third panel 3, the seventh electrode layer 44 and the eighth electrode layer 45 of the fourth panel 4, the ninth electrode layer 54 and the tenth electrode layer 55 of the fifth panel 5 and the eleventh electrode layer 64 and the twelfth electrode layer 65 of the sixth panel 6), and the electrical energy provided by the energy storage device D can respectively provide to the electrode layers in each panels correspondingly electrically connected thereto (for example, the first electrode layer 14, the second electrode layer 15, the third electrode layer 24, the fourth electrode layer 25, the fifth electrode layer 34, the sixth electrode layer 35, the seventh electrode layer 44, the eighth electrode layer 45, the ninth electrode layer 54, the tenth electrode layer 55, the eleventh electrode layer 64 and the twelfth electrode layer 65), thereby driving display layers in each panels (for example, the first display layer 13, the second display layer 23, the third display layer 33, the fourth display layer 43, the fifth display layer 53 and the sixth display layer 63), and the first reflective panel RP1 and the second reflective panel RP2 respectively display images. The electrical connection of the electrode layers in each panel and the driving circuits is only an example, but the present disclosure is not limited thereto. The first driving circuit C1 comprises, for example, a driver IC, a driving circuit board and/or a control board. The first driving circuit C1 may comprise, for example, a driver IC or a driving circuit board that provides different signals, such as scan or data signals, but the present disclosure is not limited thereto.

In one embodiment of the present disclosure, as shown in FIG. 1A, the electronic device may further comprise: a first light guide element LG1 disposed on a side of the first reflective panel RP1 away from the second reflective panel RP2; and a first light source L1 disposed adjacent to the first light guide element LG1, wherein the photoelectric conversion unit E1 is further used to provide electrical energy to the first light source L1. When the electronic device is in a dim environment, the first light source L1 may provide additional light, and most of the emitted light can be guide to the first reflective panel RP1 by the first light guide element LG1 for use, thereby improving the display quality of the first reflective panel RP1. Similarly, the electronic device may further comprise: a second light guide element LG2 disposed on a side of the second reflective panel RP2 away from the first reflective panel RP1; and a second light source L2 disposed adjacent to the second light guide element LG2, wherein the photoelectric conversion unit E1 is further used to provide electrical energy to the second light source L2. Thus, the second light source L2 may provide additional light, and most of the emitted light can be guide to the second reflective panel RP2 by the second light guide element LG2, thereby improving the display quality of the second reflective panel RP2.

In the present disclosure, the material of the first light guide element LG1 and the second light guide element LG2 may respectively comprise glass, polycarbonate (PC), polymethylmethacrylate (PMMA), polyethylene terephthalate (PET), suitable high transmittance material or a combination thereof, but the present disclosure is not limited thereto. In one embodiment of the present disclosure, even not shown in the figure, the light guide element (for example, the first light guide element LG1 and the second light guide element LG2) may respectively selectively comprise a plurality of micro-structures disposed on a side of each light guide element away from the photoelectric conversion unit E1 (that is, the light emitting side), thereby improving the light utilization. The micro-structures may comprise, for example, concave structures, convex structures or a combination thereof, but the present disclosure is not limited thereto. The first light source L1 and the second light source L2 may respectively comprise a light emitting diode (LED), and the LED may comprise, for example, an organic light emitting diode (OLED), a mini LED, a micro LED or a quantum dot LED (which may include a QLED or a QDLED), fluorescence, phosphor, other suitable materials or a combination thereof, but the present disclosure is not limited thereto.

In one embodiment of the present disclosure, as shown in FIG. 1A, the electronic device may further comprise an adhesive layer A1 and an adhesive layer A2 respectively disposed on two sides of the photoelectric conversion unit E1. For example, the adhesive layer A1 may be disposed between the first reflective panel RP1 and the photoelectric conversion unit E1, and the adhesive layer A2 may be disposed between the second reflective panel RP2 and the photoelectric conversion unit E1. Thus, the first reflective panel RP1, the second reflective panel RP2 and the photoelectric conversion unit E1 may be fixed with each other, thereby forming the electronic device of the present disclosure. More specifically, as shown in FIG. 1B, the adhesive layer A1 may be disposed between the eighth substrate 42 of the first reflective panel RP1 and the thirteenth substrate E11 of the photoelectric conversion unit E1, thereby fixing the first reflective panel RP1 and the photoelectric conversion unit E1; and the adhesive layer A2 may be disposed between the twelfth substrate 62 of the second reflective panel RP2 and the fourteenth substrate E12 of the photoelectric conversion unit E1, thereby fixing the second reflective panel RP2 and the photoelectric conversion unit E1. In one embodiment of the present disclosure, even not shown in the figure, when photoelectric conversion unit E1 selectively does not comprise the thirteenth substrate E11 and/or the fourteenth substrate E12, the adhesive layer A1 and/or the adhesive layer A2 may be selectively omitted, thereby further reducing the thickness of the electronic device.

In one embodiment of the present disclosure, as shown in FIG. 1B, adhesive layers A may be selectively disposed between the first panel 1, the third panel 3 and the fourth panel 4 of the first reflective panel RP1, thereby fixing the first panel 1, the third panel 3 and the fourth panel 4. Similarly, adhesive layers A may also be selectively disposed between the second panel 2, the fifth panel 5 and the sixth panel 6 of the second reflective panel RP2, thereby fixing the second panel 2, the fifth panel 5 and the sixth panel 6.

In the present disclosure, the adhesive layers A, the adhesive layer A1 and the adhesive layer A2 may respectively comprise a transparent material. For example, the adhesive layers A, the adhesive layer A1 and the adhesive layer A2 may respectively comprise glass adhesive, optical adhesive, silicone adhesive, adhesive tape, hot melt adhesive, AB adhesive, two-component adhesive, polymer adhesive or a combination thereof, but the present disclosure is not limited thereto.

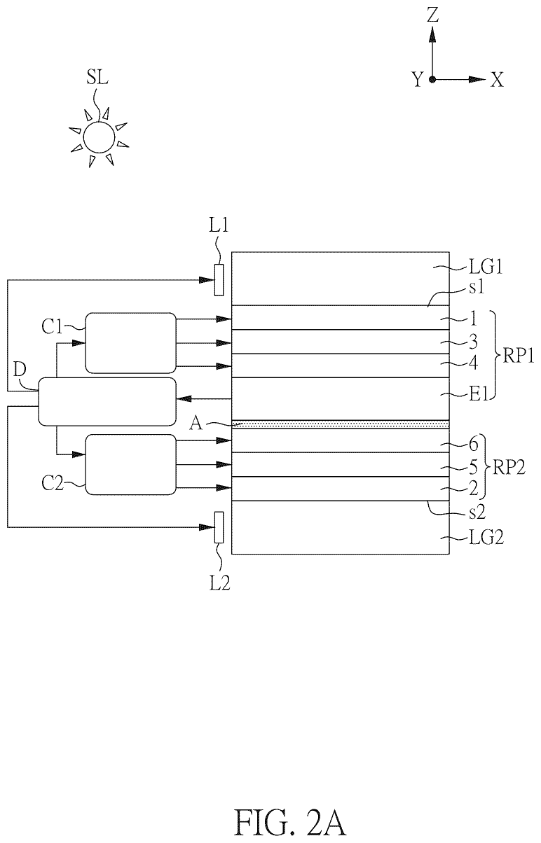

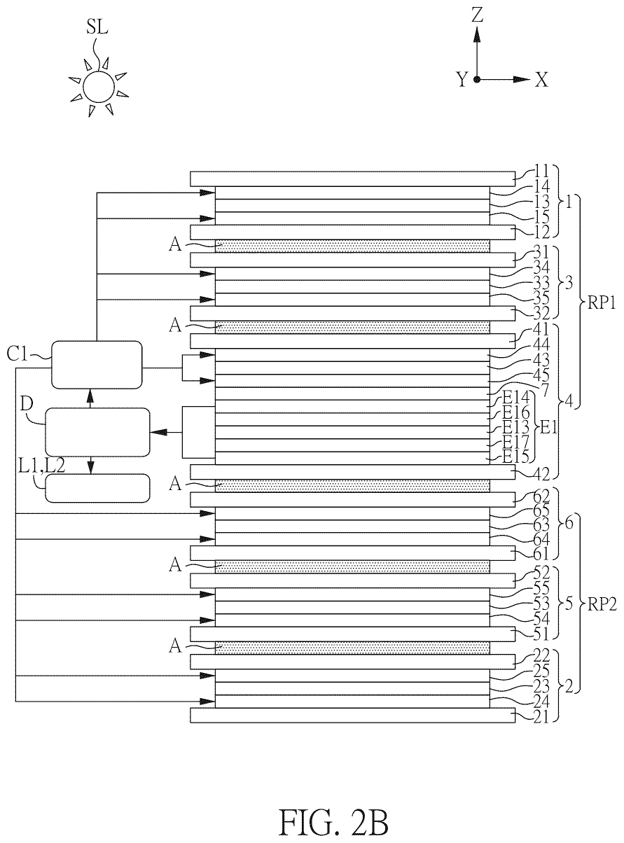

FIG. 2A and FIG. 2B are schematic views of an electronic device according to one embodiment of the present disclosure. FIG. 2A is similar to FIG. 2B, and FIG. 2B shows a detailed structure of a part of the electronic device. In addition, for convenience of explanation, some components are selectively omitted in the figures. Furthermore, the electronic device shown in FIG. 2A and FIG. 2B is similar to that shown in FIG. 1A and FIG. 1B, except for the following differences.

In one embodiment of the present disclosure, as shown in FIG. 2A, the photoelectric conversion unit E1 may be disposed in one of the first reflective panel RP1 and the second reflective panel RP2. For example, the photoelectric conversion unit E1 is disposed in the first reflective panel RP1. More specifically, as shown in FIG. 2B, the photoelectric conversion unit E1 may be, for example, disposed in the fourth panel 4 of the first reflective panel RP1, and may comprise: a photoelectric conversion layer E13 disposed between the seventh substrate 41 and the eighth substrate 42; a thirteenth electrode layer E14 disposed between the seventh substrate 41 and the photoelectric conversion layer E13; a fourteenth electrode layer E15 disposed between the eighth substrate 42 and the photoelectric conversion layer E13; a hole transport layer E16 disposed between the thirteenth electrode layer E14 and the photoelectric conversion layer E13; and an electron transport layer E17 disposed between the fourteenth electrode layer E15 and the photoelectric conversion layer E13.

In one embodiment of the present disclosure, even not shown in the figure, when the first reflective panel RP1 does not comprise the fourth panel 4, the photoelectric conversion unit E1 may be disposed in the first panel 1 or the third panel 3. In one embodiment of the present disclosure, even not shown in the figure, the photoelectric conversion unit E1 may also be disposed in the second reflective panel RP2, which are not described again here. When the photoelectric conversion unit E1 is disposed in the reflective panel (for example, the first reflective panel RP1 and/or the second reflective panel RP2), the thirteenth substrate E11 (as shown in FIG. 1B) and the fourteenth substrate E12 (as shown in FIG. 1B) of the photoelectric conversion unit E1 can be omitted, thereby reducing the thickness of the electronic device.

In one embodiment of the present disclosure, as shown in FIG. 2B, the first reflective panel RP1 may further comprise an insulating layer 7 disposed between the photoelectric conversion unit E1 and the eighth electrode layer 45. In the present disclosure, the material of the insulating layer 7 may comprise silicon nitride, silicon oxide, silicon oxynitride, silicon carbonitride, aluminum oxide, organic materials, or combinations thereof, but the present disclosure is not limited thereto.

In the present disclosure, other detail features of the electronic device may be referred to those of FIG. 1B, which are not described again here. In addition, other units and materials of the electronic device may also be referred to those described above, which are not described again here.

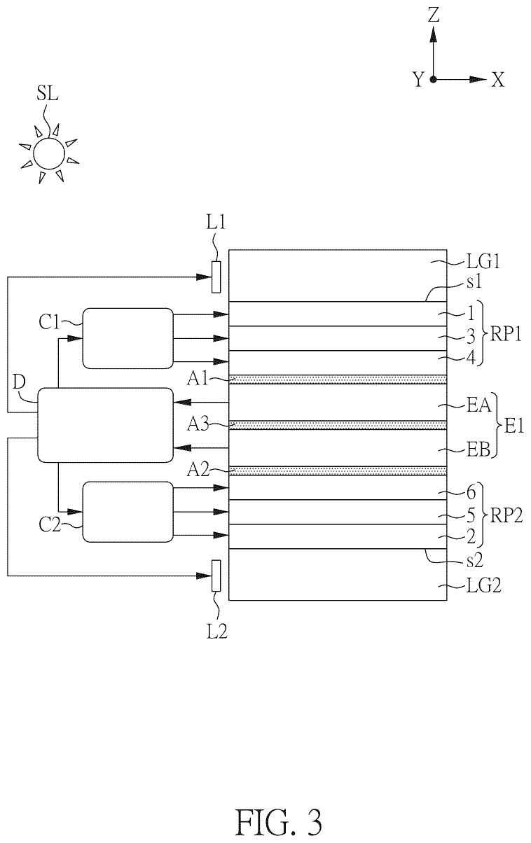

FIG. 3 is a schematic view of an electronic device according to one embodiment of the present disclosure. The electronic device of FIG. 3 is similar to that of FIG. 1A, except for the following differences.

In one embodiment of the present disclosure, as shown in FIG. 3, the photoelectric conversion unit E1 is disposed between the first reflective panel RP1 and the second reflective panel RP2 and comprising a first photoelectric conversion unit EA and a second photoelectric conversion unit EB adjacent thereto. The first photoelectric conversion unit EA may absorb at least part of light passing through the first reflective panel RP1, and convert the light into electrical energy to provide to the energy storage device D; and the second photoelectric conversion unit EB may absorb at least part of the light passing through the second reflective panel RP2, and convert the light into electrical energy to provide to the energy storage device D.

In one embodiment of the present disclosure, as shown in FIG. 3, the electronic device may further comprise an adhesive layer A1, an adhesive layer A2 and an adhesive layer A3, wherein the adhesive layer A1 and the adhesive layer A2 may be respectively disposed on two sides of the photoelectric conversion unit E1, and the adhesive layer A3 is disposed between the first photoelectric conversion unit EA and the second photoelectric conversion unit EB. More specifically, the adhesive layer A1 may be disposed between the first reflective panel RP1 and the first photoelectric conversion unit EA, the adhesive layer A2 may be disposed between the second reflective panel RP2 and the second photoelectric conversion unit EB, and the adhesive layer A3 may be disposed between the first photoelectric conversion unit EA and the second photoelectric conversion unit EB. Thus, the first reflective panel RP1, the second reflective panel RP2, the first photoelectric conversion unit EA and the second photoelectric conversion unit EB can be fixed to each other to form the electronic device of the present disclosure. In some embodiments (not shown in the figure), the adhesive layer A3 between the first photoelectric conversion unit EA and the second photoelectric conversion unit EB may be omitted. The adhesive layer A1, the adhesive layer A2 and the adhesive layer A3 may be a whole or patterned adhesive layer.

In the present disclosure, the first photoelectric conversion unit EA and the second photoelectric conversion unit EB may be, for example, a perovskite solar cell, and the structure thereof may be as shown in the photoelectric conversion unit E1 of FIG. 1B, which are not described again here. The first photoelectric conversion unit EA and the second photoelectric conversion unit EB may also be a silicon wafer solar cell, a silicon wafer stacked perovskite solar cell, a silicon wafer stacked amorphous silicon solar cell or a silicon wafer stacked organic solar cell, but the present disclosure is not limited thereto. In the present disclosure, the adhesive layer A1, the adhesive layer A2 and the adhesive layer A3 may respectively comprise a transparent material, and the material of the adhesive layer A1, the adhesive layer A2 and the adhesive layer A3 may respectively comprise glass adhesive, optical adhesive, silicone adhesive, adhesive tape, hot melt adhesive, AB adhesive, two-component adhesive, polymer adhesive or a combination thereof, but the present disclosure is not limited thereto. In one embodiment of the present disclosure, the adhesive layer A3 may selectively comprise a non-transparent material, such as black or other color adhesive material, but the present disclosure is not limited thereto. When the adhesive layer A3 comprise a non-transparent material, the contract of the first reflective panel RP1 and/or the second reflective panel RP2 can be increased, thereby improving the display quality. In one embodiment, the adhesive layer A3 may also comprise a composite layer, for example, comprising a black or other color matrix and two adhesive materials respectively disposed on two sides of the matrix; and at this time, the two adhesive materials may respectively comprise a transparent material or a non-transparent material.

In the present disclosure, other detail features of the electronic device may be as described in FIG. 1A and FIG. 1B, which are not described again here. In addition, other units and materials of the electronic device may be as described above, which are not described again here.

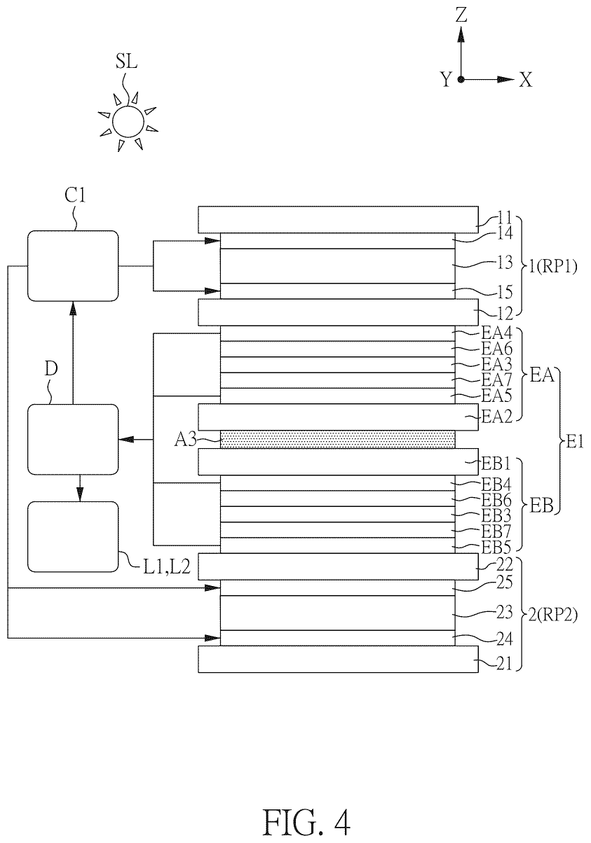

FIG. 4 is a schematic view of an electronic device according to one embodiment of the present disclosure. The electronic device of FIG. 4 is similar to that shown in FIG. 3, except for the following differences. In addition, for the convenience of explanation, some components are omitted in the figure.

In one embodiment of the present disclosure, as shown in FIG. 4, the first reflective panel RP1 comprises a first panel 1, and the second reflective panel RP2 comprises a second panel 2. The photoelectric conversion unit E1 is disposed between the first reflective panel RP1 and the second reflective panel RP2 and comprising a first photoelectric conversion unit EA and a second photoelectric conversion unit EB adjacent thereto. The first photoelectric conversion unit EA comprises a first photoconversion layer EA3 and two electrodes disposed on two sides of the first photoconversion layer EA3 (an electrode layer EA4 and an electrode layer EA5). More specifically, the first photoelectric conversion unit EA comprises: a substrate EA2 disposed opposite to the second substrate 12; a first photoconversion layer EA3 disposed between the substrate EA2 and the second substrate 12; an electrode layer EA4 disposed between the second substrate 12 and the first photoconversion layer EA3; an electrode layer EA5 disposed between the substrate EA2 and the first photoconversion layer EA3; a hole transport layer EA6 disposed between the electrode layer EA4 and the first photoconversion layer EA3; and an electron transport layer EA7 disposed between the electrode layer EA5 and the first photoconversion layer EA3. The second photoelectric conversion unit EB comprises a second photoconversion layer EB3 and two electrodes disposed on two sides of the second photoconversion layer EB3 (the electrode layer EB4 and the electrode layer EB5). More specifically, the second photoelectric conversion unit EB comprises: a substrate EB1 disposed opposite to the fourth substrate 22; a second photoconversion layer EB3 disposed between the substrate EB1 and the fourth substrate 22; an electrode layer EB4 disposed between the substrate EB1 and the second photoconversion layer EB3; an electrode layer EB5 disposed between the fourth substrate 22 and the second photoconversion layer EB3; a hole transport layer EB6 disposed between the electrode layer EB4 and the second photoconversion layer EB3; and an electron transport layer EB7 disposed between the electrode layer EB5 and the second photoconversion layer EB3. The first photoelectric conversion unit EA may absorb the light (for example, the external light SL) passing through the first reflective panel RP1 (or the first panel 1), and convert the light into electrical energy to provide to the energy storage device D; and the second photoelectric conversion unit EB may absorb the light (for example, external light SL) passing through the second reflective panel RP2 (or the second panel 2), and convert the light into electrical energy to provide to the energy storage device D.

In the present disclosure, the materials of the substrate EA2 and the substrate EB1 may be similar to that of the thirteenth substrate E11 (as shown in FIG. 1B); the materials of the electrode layer EA4, the electrode layer EA5, the electrode layer EB4 and the electrode layer EB5 may be respectively similar to that of the thirteenth electrode layer E14 (as shown in FIG. 1B); the materials of the first photoconversion layer EA3 and the second photoconversion layer EB3 may be respectively similar to that of the photoelectric conversion layer E13 (as shown in FIG. 1B); the materials of the hole transport layer EA6 and the hole transport layer EB6 may be respectively similar to that of the hole transport layer E16 (as shown in FIG. 1B); the materials of the electron transport layer EA7 and the electron transport layer EB7 may be respectively similar to that of the electron transport layer E17 (as shown in FIG. 1B), which are not described again here. The first photoelectric conversion unit EA and the second photoelectric conversion unit EB may be, for example, a perovskite solar cell or other suitable cell materials respectively. The first photoelectric conversion unit EA and the second photoelectric conversion unit EB shown in FIG. 4 may respectively be a perovskite solar cells with a n-i-p structure or other suitable cell materials, but the present disclosure is not limited thereto. In other embodiments, the first photoelectric conversion unit EA and the second photoelectric conversion unit EB may respectively a perovskite solar cell with a p-i-n structure or other suitable cells.

In one embodiment of the present disclosure, as shown in FIG. 4, in two electrodes on two sides of the first photoconversion layer EA3 (for example, the electrode layer EA4 and the electrode layer EA5), the one adjacent to the second photoelectric conversion unit EB (for example, the electrode layer EA5) may be selectively a non-transparent conductive layer, that is, the electrode layer EA5 may be prepared by a non-transparent conductive material. Thus, the contract of the first reflective panel RP1 (or the first panel 1) can be increased. Similarly, in two electrodes on two sides of the second photoconversion layer EB3 (for example, the electrode layer EB4 and the electrode layer EB5), the one adjacent to the first photoelectric conversion unit EA (for example, the electrode layer EB4) may be selectively a non-transparent conductive layer, that is, the electrode layer EB4 may be prepared by a non-transparent conductive material. Thus, the contract of the second reflective panel RP2 (or the second panel 2) can be increased. The non-transparent conductive material may be, for example, a metal material, and suitable metal material may comprise gold, silver, copper, palladium, platinum, ruthenium, aluminum, cobalt, nickel, titanium, molybdenum, manganese, tungsten, an alloy thereof or a combination thereof, but the present disclosure is not limited thereto.

In one embodiment of the present disclosure, as shown in FIG. 4, the electrode layer EA4 of the first photoelectric conversion unit EA may be directly disposed on the second substrate 12 of the first panel 1, and the electrode layer EB5 of the second photoelectric conversion unit EB may be directly disposed on the fourth substrate 22 of the second panel 2. Thus, the adhesive layer A1 (as shown in FIG. 3) and the adhesive layer A2 (as shown in FIG. 3) can be omitted, thereby reducing the thickness of the electronic device.

In one embodiment of the present disclosure, the first reflective panel RP1 and/or the second reflective panel RP2 may respectively comprise a plurality of panels, as shown in FIG. 3, and the detail features of each panel may be as described in FIG. 1B, which are not described again here. In addition, other units and materials of the electronic device may be as described above, which are not described again here.

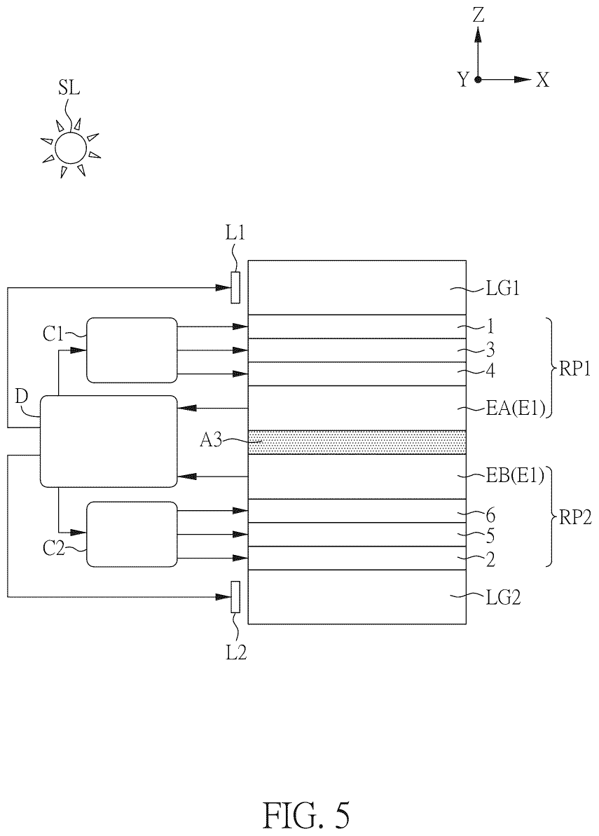

FIG. 5 is a schematic view of an electronic device according to one embodiment of the present disclosure. The electronic device of FIG. 5 is similar to that shown in FIG. 2A and FIG. 2B, except for the following differences.

In one embodiment of the present disclosure, as shown in FIG. 5, the photoelectric conversion unit E1 may be disposed in one of the first reflective panel RP1 and the second reflective panel RP2, and comprise a first photoelectric conversion unit EA and a second photoelectric conversion unit EB adjacent thereto. More specifically, the first photoelectric conversion unit EA is disposed in the first reflective panel RP1, the second photoelectric conversion unit EB is disposed in the second reflective panel RP2, and the first photoelectric conversion unit EA and the second photoelectric conversion unit EB may be fixed to each other through the adhesive layer A3, thereby forming the electronic device of the present disclosure. The first photoelectric conversion unit EA may absorb at least part of the light passing through the first panel 1, the third panel 3 and the fourth panel 4, and convert the light into electrical energy to provide to the energy storage device D; the second photoelectric conversion unit EB may absorb at least part of the light passing through the second panel 2, the fifth panel 5 and the sixth panel 6, and convert the light into electrical energy to provide to the energy storage device D.

In the present disclosure, the first photoelectric conversion unit EA and the second photoelectric conversion unit EB may be, for example, a perovskite solar cell or other suitable cells, and the structure thereof may be as shown in the photoelectric conversion unit E1 of FIG. 2B, which are not described again here. The first photoelectric conversion unit EA and the second photoelectric conversion unit EB may also be a silicon wafer solar cell, a silicon wafer stacked perovskite solar cell, a silicon wafer stacked amorphous silicon solar cell or a silicon wafer stacked organic solar cell, but the present disclosure is not limited thereto. In the present disclosure, the adhesive layer A3 may respectively comprise a transparent material or a non-transparent material, and the material of the adhesive layer A3 may comprise glass adhesive, optical adhesive, silicone adhesive, adhesive tape, hot melt adhesive, AB adhesive, two-component adhesive, polymer adhesive or a combination thereof, but the present disclosure is not limited thereto. When the adhesive layer A3 comprises a non-transparent material, the contract of the first reflective panel RP1 and/or the second reflective panel RP2 can be increased, thereby improving the display quality.

In the present disclosure, other detail features of the electronic device may be as described in FIG. 2A and FIG. 2B, which are not described again here. In addition, other units and materials of the electronic device may also be as described above, which are not described again here.

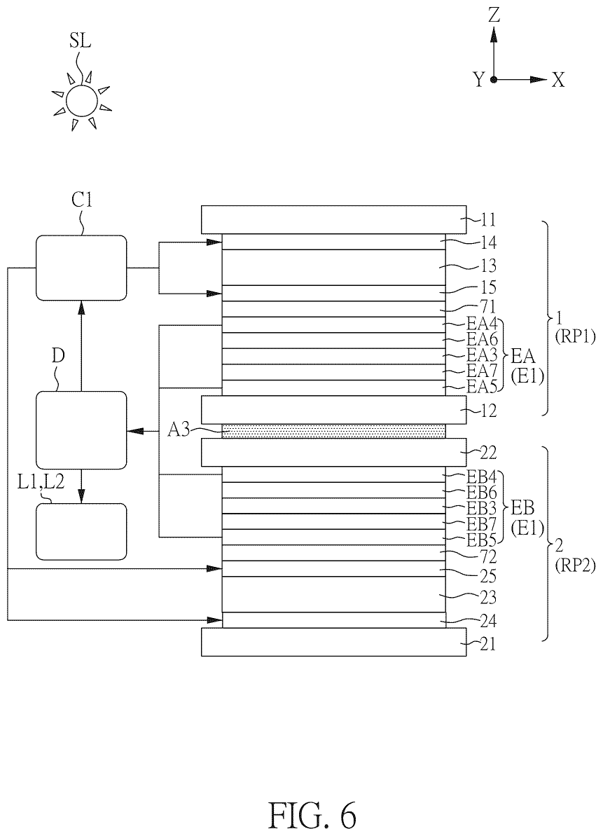

FIG. 6 is a schematic view of an electronic device according to one embodiment of the present disclosure. The electronic device of FIG. 6 is similar to that shown in FIG. 5, except for the following differences. For the convenience of explanation, some components are omitted in the figure.

In one embodiment of the present disclosure, as shown in FIG. 6, the first reflective panel RP1 comprises a first panel 1, and the second reflective panel RP2 comprises a second panel 2. The photoelectric conversion unit E1 comprises a first photoelectric conversion unit EA and a second photoelectric conversion unit EB adjacent thereto. The first photoelectric conversion unit EA is disposed in the first panel 1, and the second photoelectric conversion unit EB is disposed in the second panel 2. The first photoelectric conversion unit EA comprises: a first photoconversion layer EA3 disposed between the first substrate 11 and the second substrate 12; an electrode layer EA4 disposed between the first substrate 11 and the first photoconversion layer EA3; an electrode layer EA5 disposed between the second substrate 12 and the first photoconversion layer EA3; a hole transport layer EA6 disposed between the electrode layer EA4 and the first photoconversion layer EA3; and an electron transport layer EA7 disposed between the electrode layer EA5 and the first photoconversion layer EA3. The second photoelectric conversion unit EB comprises: a second photoconversion layer EB3 disposed between the third substrate 21 and the fourth substrate 22; an electrode layer EB4 disposed between the fourth substrate 22 and the second photoconversion layer EB3; an electrode layer EB5 disposed between the third substrate 21 and the second photoconversion layer EB3; a hole transport layer EB6 disposed between the electrode layer EB4 and the second photoconversion layer EB3; and an electron transport layer EB7 disposed between the electrode layer EB5 and the second photoconversion layer EB3. The first photoelectric conversion unit EA may absorb at least part of the light passing through the first display layer 13, and convert the light into electrical energy to provide to the energy storage device D; the second photoelectric conversion unit EB may absorb at least part of the light passing through the second display layer 23, and convert the light into electrical energy to provide to the energy storage device D.

In the present disclosure, the materials of the electrode layer EA4, the electrode layer EA5, the electrode layer EB4 and the electrode layer EB5 may be similar to that of the thirteenth electrode layer E14 (as shown in FIG. 2B) respectively; the materials of the first photoconversion layer EA3 and the second photoconversion layer EB3 may be similar to that of the photoelectric conversion layer E13 (as shown in FIG. 2B) respectively; the materials of the hole transport layer EA6 and the hole transport layer EB6 may be similar to that of the hole transport layer E16 (as shown in FIG. 2B) respectively; the materials of the electron transport layer EA7 and the electron transport layer EB7 may be similar to that of the electron transport layer E17 (as shown in FIG. 2B) respectively, which are not described again here. The first photoelectric conversion unit EA and the second photoelectric conversion unit EB may respectively be, for example, a perovskite solar cell. The first photoelectric conversion unit EA and the second photoelectric conversion unit EB shown in FIG. 6 may respectively a perovskite solar cell with an n-i-p structure or other suitable cells, but the present disclosure is not limited thereto. In other embodiments, the first photoelectric conversion unit EA and the second photoelectric conversion unit EB may respectively be a perovskite solar cell with a p-i-n structure or other suitable cells.

In one embodiment of the present disclosure, as shown in FIG. 6, in two electrodes on two sides of the first photoconversion layer EA3 (for example, the electrode layer EA4 and the electrode layer EA5), the one adjacent to the second photoelectric conversion unit EB (for example, the electrode layer EA5) may be selectively a non-transparent conductive layer. That is, the electrode layer EA5 may be prepared by a non-transparent conductive material. Thus, the contract of the display image of the first reflective panel RP1 (or the first panel 1) can be increased. Similarly, in the two electrodes on two sides of the second photoconversion layer EB3 (for example, the electrode layer EB4 and the electrode layer EB5), the one adjacent to the first photoelectric conversion unit EA (for example, the electrode layer EB4) may selectively be a non-transparent conductive layer, that is, the electrode layer EB4 may be prepared by a non-transparent conductive material. Thus, the contract of display image of the second reflective panel RP2 (or the second panel 2) can be increased. The non-transparent conductive material may be, for example, a metal material, and suitable metal material may comprise gold, silver, copper, palladium, platinum, ruthenium, aluminum, cobalt, nickel, titanium, molybdenum, manganese, tungsten, an alloy thereof or a combination thereof, but the present disclosure is not limited thereto.

In one embodiment of the present disclosure, as shown in FIG. 6, the first reflective panel RP1 may further comprise an insulating layer 71 disposed between the first photoelectric conversion unit EA and the second electrode layer 15; the second reflective panel RP2 may further comprise an insulating layer 72 disposed between the second photoelectric conversion unit EB and the fourth electrode layer 25. In the present disclosure, the material of the insulating layer 71 and the insulating layer 72 may respectively comprise silicon nitride, silicon oxide, silicon oxynitride, silicon carbonitride, aluminum oxide, organic materials or a combination thereof, but the present disclosure is not limited thereto.

In one embodiment of the present disclosure, the first reflective panel RP1 and/or the second reflective panel RP2 may respectively comprise a plurality of panels, as shown in FIG. 5, and the detail features of each panel may be as described in FIG. 2B, which are not described again here. In addition, other units and materials of the electronic device may also be as described above, which are not described again here.

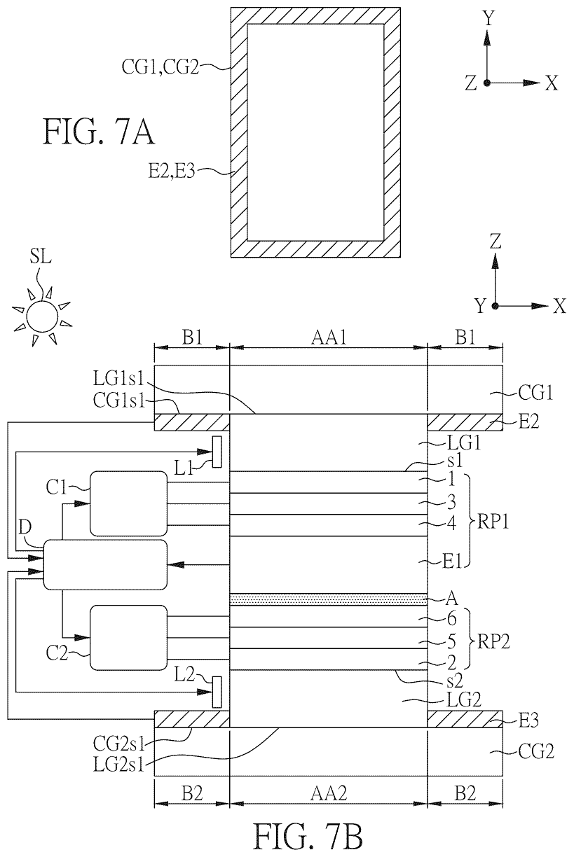

FIG. 7A is a top schematic view of a part of an electronic device according to one embodiment of the present disclosure. FIG. 7B is a cross-sectional schematic view of an electronic device according to one embodiment of the present disclosure. The electronic device shown in FIG. 7A and FIG. 7B is similar to that shown in FIG. 2A and FIG. 2B, except for the following differences. In addition, for convenience of explanation, some components are selectively omitted in the figures.

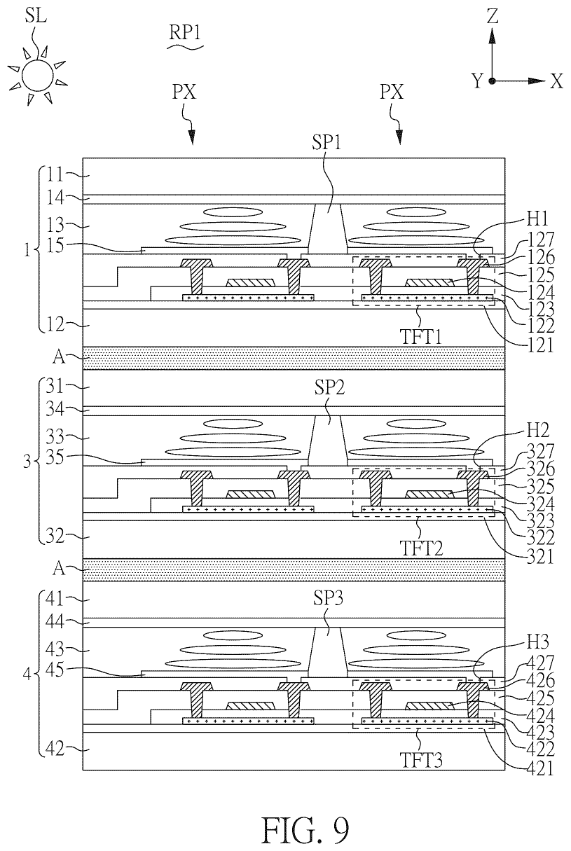

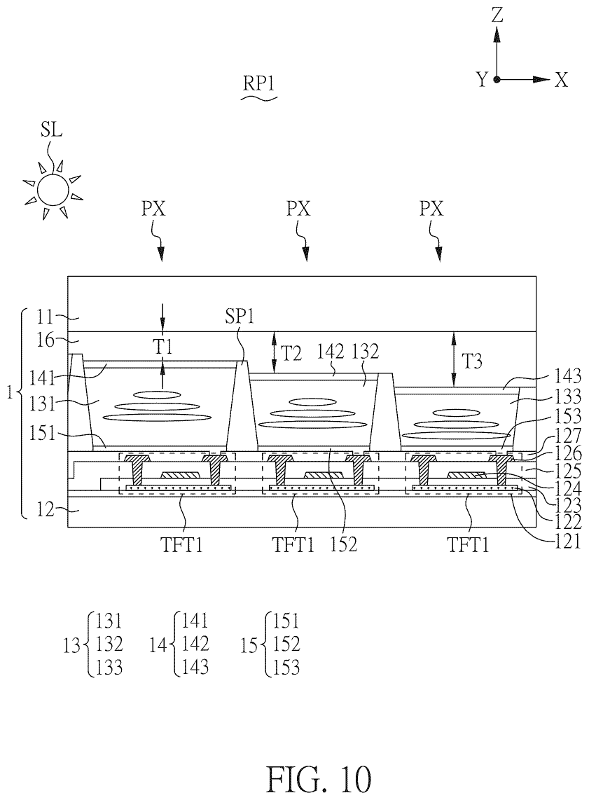

In one embodiment of the present disclosure, as shown in FIG. 7A and FIG. 7B, the electronic device may further comprise a first protective substrate CG1 disposed on a side of the first reflective panel RP1 away from the second reflective panel RP2. The first protective substrate CG1 has an active region AA1 and a peripheral region B1. The electronic device may further comprise a second photoelectric conversion unit E2 disposed in the peripheral region B1 of the first protective substrate CG1. The “active region AA1” refers to the region overlapping a plurality of pixel areas of the first reflective panel RP1 in the top view direction Z of the electronic device (referring to the pixel areas PX shown in FIG. 9 or FIG. 10). The “peripheral region B1” refers to, for example, the region excluding the active region AA1 of the first protective substrate CG1. More specifically, the first protective substrate CG1 may be disposed on a surface LG1s1 of the first light guide element LG1 away from the first reflective panel RP1, and comprising the active region AA1 and the peripheral region B1, and the peripheral region B1 is disposed surrounding the active region AA1, wherein the second photoelectric conversion unit E2 is disposed on a surface CG1s1 of the first protective substrate CG1 adjacent to the first reflective panel RP1. The second photoelectric conversion unit E2 may absorb at least part of the incident light (for example, the external light SL) incident on the peripheral region B1 of the first protective substrate CG1, and convert it into electrical energy to provide to the energy storage device D, thereby improving the photoelectric conversion efficiency. In addition, the second photoelectric conversion unit E2 may be used as a shielding layer for improving the display effect of the electronic device. The second photoelectric conversion unit E2 may be, for example, disposed overlapping the peripheral region B1, and even partially overlapping the active region AA1. The second photoelectric conversion unit E2 may be, for example, not overlapped or at least partially overlapped with the first light guide element LG1. The second photoelectric conversion unit E2 may, for example, overlap the first light source L1 to block the first light source L1 which may affect the viewing experience.

In one embodiment of the present disclosure, as shown in FIG. 7A and FIG. 7B, the electronic device may further comprise: a second protective substrate CG2 disposed on a side of the second reflective panel RP2 away from the first reflective panel RP1. The second protective substrate CG2 has an active region AA2 and a peripheral region B2. The electronic device may further comprise a third photoelectric conversion unit E3 disposed in the peripheral region B2 of the second protective substrate CG2. The “active region AA2” referred to the region overlapping a plurality of pixel areas (not shown) of the second reflective panel RP2 in the top view direction Z of the electronic device, and the pixel areas (not shown) of the second reflective panel RP2 may be defined as the plurality of pixel areas PX of the first reflective panel RP1 shown in FIG. 9 or FIG. 10. The “peripheral region B2” refers to, for example, the region excluding the active region AA2 of the second protective substrate CG2. More specifically, the second protective substrate CG2 may be disposed on a surface LG2s1 of the second light guide element LG2 away from the second reflective panel RP2, and comprises an active region AA2 and a peripheral region B2 disposed surrounding the active region AA2, wherein the third photoelectric conversion unit E3 is disposed on a surface CG2s1 of the second protective substrate CG2 adjacent to the second reflective panel RP2. The third photoelectric conversion unit E3 may absorb at least part of the incident light (for example, external light SL) incident into the peripheral region B2 of the second protective substrate CG2, and convert it into electrical energy to provide to the energy storage device D, thereby improving the photoelectric conversion efficiency. In addition, the third photoelectric conversion unit E3 may also be used as a shielding layer for improving the taste effect of the electronic device. The third photoelectric conversion unit E3 may be, for example, disposed overlapping the peripheral region B2, and even may partially overlap the active region AA2. The third photoelectric conversion unit E3 may be, for example, not overlapped or at least partially overlapped with the second light guide element LG2. The third photoelectric conversion unit E3 may, for example, overlap the second light source L2 to block the second light source L2 which may affect the viewing experience.

In one embodiment (not shown in the figure), an adhesive layer may be disposed between the first light guide element LG1 and the first reflective panel RP1, and another adhesive layer may be disposed between the second light guide element LG2 and the second reflective panel RP2. The adhesive layer may be used to fix the first light guide element LG1 and the first reflective panel RP1 with each other, and another adhesive layer may be used to fix the second light guide element LG2 and the second reflective panel RP2 with each other. The adhesive layer and another adhesive layer may respectively comprise glass adhesive, optical adhesive, silicone adhesive, adhesive tape, hot melt adhesive, AB adhesive, two-component adhesive, polymer adhesive or a combination thereof, but the present disclosure is not limited thereto.

In the present disclosure, the material of the first protective substrate CG1 and the second protective substrate CG2 may be respectively similar to that of the first substrate 11, which are not described again here. Or, an organic material may be used to prepare the first protective substrate CG1 and the second protective substrate CG2, such as polyimide (PI), polyethylene (PE), polyvinylchloride (PVC), polystyrene (PS), acrylic, fluoropolymer, polyester, nylon or other suitable organic material, but the present disclosure is not limited thereto. In the present disclosure, the second photoelectric conversion unit E2 and the third photoelectric conversion unit E3 may be, for example, a perovskite solar cell or other suitable cells, and the structure thereof may be as the photoelectric conversion unit E1 of FIG. 2B respectively, which are not described again here. The second photoelectric conversion unit E2 and the third photoelectric conversion unit E3 may be a silicon wafer solar cell, a silicon wafer stacked perovskite solar cell, a silicon wafer stacked amorphous silicon solar cell or a silicon wafer stacked organic solar cell. In the present disclosure, other detail features of the electronic device may be referred to that shown in FIG. 2A and FIG. 2B, which are not described again here. In addition, other units and materials of the electronic device may also be as described above, which are not described again here. In addition, even not shown in the figure, in other embodiments of the present disclosure, the photoelectric conversion unit E1 may also be disposed between the first reflective panel RP1 and the second reflective panel RP2 as shown in FIG. 1A, which are not described again here.

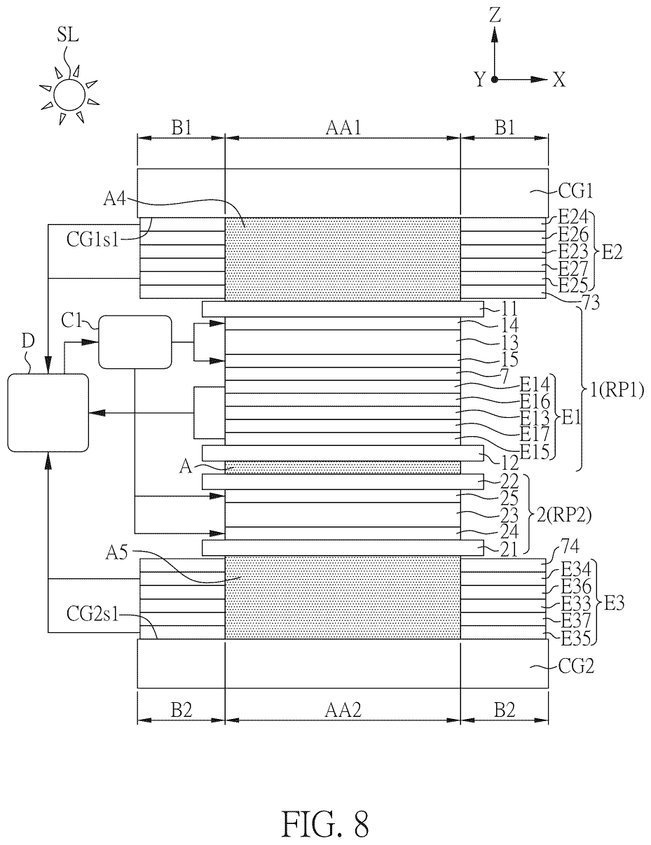

FIG. 8 is a cross-sectional schematic view of an electronic device according to one embodiment of the present disclosure. The electronic device shown in FIG. 8 is similar to that shown in FIG. 7A and FIG. 7B, except for the following differences.

In one embodiment of the present disclosure, as shown in FIG. 8, the first reflective panel RP1 comprises a first panel 1, the second reflective panel RP2 comprises a second panel 2, and the first reflective panel RP1 and the second reflective panel RP2 are fixed through an adhesive layer A. The photoelectric conversion unit E1 is disposed in the first reflective panel RP1, but the present disclosure is not limited thereto. The second photoelectric conversion unit E2 is disposed in the peripheral region B1 of the first protective substrate CG1, and the third photoelectric conversion unit E3 is disposed in the peripheral region B2 of the second protective substrate CG2. More specifically, the second photoelectric conversion unit E2 is disposed on a surface CG1s1 of the first protective substrate CG1 adjacent to the first reflective panel RP1, and the third photoelectric conversion unit E3 is disposed on the surface CG2s1 of the second protective substrate CG2 adjacent to the second reflective panel RP2.

In one embodiment of the present disclosure, as shown in FIG. 8, the second photoelectric conversion unit E2 may comprise: a photoelectric conversion layer E23; an electrode layer E24 and an electrode layer E25 respectively disposed on two sides of the photoelectric conversion layer E23; a hole transport layer E26 disposed between the electrode layer E24 and the photoelectric conversion layer E23; an electron transport layer E27 disposed between the electrode layer E25 and the photoelectric conversion layer E23; and an insulating layer 73, wherein the electrode layer E25 is disposed between the insulating layer 73 and the electron transport layer E27. The third photoelectric conversion unit E3 may comprise: a photoelectric conversion layer E33; an electrode layer E34 and an electrode layer E35 respectively disposed on two sides of the photoelectric conversion layer E33; a hole transport layer E36 disposed between the electrode layer E34 and the photoelectric conversion layer E33; an electron transport layer E37 disposed between the electrode layer E35 and the photoelectric conversion layer E33; and an insulating layer 74, wherein the electrode layer E34 is disposed between the insulating layer 74 and the hole transport layer E36. The second photoelectric conversion unit E2 and the third photoelectric conversion unit E3 shown in FIG. 8 may be respectively a perovskite solar cell with an n-i-p structure or other suitable cells, but the present disclosure is not limited thereto. In other embodiments, the second photoelectric conversion unit E2 and the third photoelectric conversion unit E3 may also respectively a perovskite solar cell with a p-i-n structure or other suitable cells.

In the present disclosure, the materials of the photoelectric conversion layer E23 and the photoelectric conversion layer E33 may be similar to that of the photoelectric conversion layer E13 respectively; the materials of the electrode layer E24, the electrode layer E25, the electrode layer E34 and the electrode layer E35 may be respectively similar to that of the thirteenth electrode layer E14; the materials of the hole transport layer E26 and the hole transport layer E36 may be respectively similar to that of the hole transport layer E16; the materials of the electron transport layer E27 and the electron transport layer E37 may be respectively similar to that of the electron transport layer E17, which are not described again here. The materials of the insulating layer 73 and the insulating layer 74 may respectively comprise silicon nitride, silicon oxide, silicon oxynitride, silicon carbonitride, aluminum oxide, organic materials, or a combination thereof, but the present disclosure is not limited thereto. In one embodiment, the electrode layer E25, the electrode layer E34, the insulating layer 73 and/or the insulating layer 74 may selectively comprise a non-transparent material to improve the light shielding effect.

In one embodiment of the present disclosure, as shown in FIG. 8, the electronic device may further comprise: an adhesive layer A4 disposed between the first protective substrate CG1 and the first reflective panel RP1; and another adhesive layer A5 disposed between the second protective substrate CG2 and the second reflective panel RP2. The adhesive layer A4 may be used to fix the first protective substrate CG1 and the first reflective panel RP1, and the adhesive layer A5 may be used to fix the second protective substrate CG2 and the second reflective panel RP2, thereby forming the electronic device of the present disclosure. In one embodiment of the present disclosure, as shown in FIG. 8, in the top view direction Z of the electronic device, the adhesive layer A4 and the second photoelectric conversion unit E2 are not overlapped, and the adhesive layer A5 and the third photoelectric conversion unit E3 are not overlapped, but the present disclosure is not limited thereto. In the present disclosure, the adhesive layer A4 and the adhesive layer A5 may respectively comprise a transparent material. For example, the adhesive layer A4 and the adhesive layer A5 may respectively comprise glass adhesive, optical adhesive, silicone adhesive, adhesive tape, hot melt adhesive, AB adhesive, two-component adhesive, polymer adhesive or a combination thereof, but the present disclosure is not limited thereto.

In the present disclosure, other detail features of the electronic device may be referred to those shown in FIG. 7A, FIG. 7B and FIG. 2B, which are not described again here. In addition, other units and materials of the electronic device may be as described above, which are not described again here.

FIG. 9 is a cross-sectional schematic view of a part of an electronic device according to one embodiment of the present disclosure. The first reflective panel RP1 shown in FIG. 9 is similar to that shown in FIG. 1B, except for the following differences.

In one embodiment of the present disclosure, as shown in FIG. 9, the first reflective panel RP1 may be, for example, active driven. More specifically, the first panel 1 may further comprise: an insulating layer 121 disposed on the second substrate 12; a semiconductor layer 122 disposed on the insulating layer 121; a gate insulating layer 123 disposed on the semiconductor layer 122; a gate electrode layer 124 disposed on the gate insulating layer 123; an insulating layer 125 disposed on the gate electrode layer 124; a source-drain electrode layer 126 disposed on the insulating layer 125; and an insulating layer 127 disposed on the source-drain electrode layer 126, wherein the second electrode layer 15 is electrically connected to the source-drain electrode layer 126 through a via H1 of the insulating layer 127. The semiconductor layer 122, the gate electrode layer 124 and the source-drain electrode layer 126 may form a transistor TFT1. The transistor TFT1 may transmit driving signals to the second electrode layer 15, thereby driving the first display layer 13. Similarly, the third panel 3 may further comprise: an insulating layer 321 disposed on the sixth substrate 32; a semiconductor layer 322 disposed on the insulating layer 321; a gate insulating layer 323 disposed on the semiconductor layer 322; a gate electrode layer 324 disposed on the gate insulating layer 323; an insulating layer 325 disposed on the gate electrode layer 324; a source-drain electrode layer 326 disposed on the insulating layer 325; and an insulating layer 327 disposed on the source-drain electrode layer 326, wherein the sixth electrode layer 35 may be electrically connected to the source-drain electrode layer 326 through a via H2 of the insulating layer 327. The semiconductor layer 322, the gate electrode layer 324 and the source-drain electrode layer 326 may form a transistor TFT2. The transistor TFT2 may transmit driving signals to the sixth electrode layer 35, thereby driving the third display layer 33. The fourth panel 4 may further comprise: an insulating layer 421 disposed on the eighth substrate 42; a semiconductor layer 422 disposed on the insulating layer 421; a gate insulating layer 423 disposed on the semiconductor layer 422; a gate electrode layer 424 disposed on the gate insulating layer 423; an insulating layer 425 disposed on the gate electrode layer 424; a source-drain electrode layer 426 disposed on the insulating layer 425; and an insulating layer 427 disposed on the source-drain electrode layer 426, wherein the eighth electrode layer 45 may be electrically connected to the source-drain electrode layer 426 through a via H3 of the insulating layer 427. The semiconductor layer 422, the gate electrode layer 424 and the source-drain electrode layer 426 may form a transistor TFT3. The transistor TFT3 may transmit driving signals to the eighth electrode layer 45, thereby driving the fourth display layer 43.

In the present disclosure, the materials of the insulating layer 121, the gate insulating layer 123, the insulating layer 125, the insulating layer 127, the insulating layer 321, the gate insulating layer 323, the insulating layer 325, the insulating layer 327, the insulating layer 421, the gate insulating layer 423, the insulating layer 425 and the insulating layer 427 may respectively comprise silicon nitride, silicon oxide, silicon oxynitride, silicon carbonitride, aluminum oxide, organic materials, or a combination thereof, but the present disclosure is not limited thereto. The materials of the semiconductor layer 122, the semiconductor layer 322 and the semiconductor layer 422 may respectively comprise amorphous silicon, polycrystalline silicon (such as low-temperature polysilicon (LTPS)) or oxide semiconductors (such as indium gallium zinc oxide (IGZO) or indium gallium oxide (IGO)), but the present disclosure is not limited thereto. The materials of the gate electrode layer 124, the source-drain electrode layer 126, the gate electrode layer 324, the source-drain electrode layer 326, the gate electrode layer 424 and the source-drain electrode layer 426 may respectively comprise a metal, a metal oxide, an alloy thereof or a combination thereof, for example, gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto.

In one embodiment of the present disclosure, as shown in FIG. 9, the first panel 1 may further comprise a spacer SP1 disposed between the first substrate 11 and the second substrate 12; the third panel 3 may further comprise a spacer SP2 disposed between the fifth substrate 31 and the sixth substrate 32; and the fourth substrate 4 may further comprise a spacer SP3 disposed between the seventh substrate 41 and the eighth substrate 42. The spacer SP1, the spacer SP2 and the spacer SP3 may be used to maintain the thicknesses of the first display layer 13, the third display layer 33 and the fourth display layer 43, to reduce damage to components within the electronic device or the impact on the uniformity of the first display layer 13, the third display layer 33, and the fourth display layer 43 in different areas when the electronic device is squeezed by external force. In the present disclosure, the materials of the spacer SP1, the spacer SP2 and the spacer SP3 may respectively comprise a resin, an organic material, other suitable material or a combination thereof, but the present disclosure is not limited thereto. In the present disclosure, the cross-sectional shapes of the spacer SP1, the spacer SP2 and the spacer SP3 are not particularly limited, and may be, for example, cylinder, rectangular prism, trapezoidal prism, triangular prism, cone, triangular pyramid or other irregular shaped prisms respectively, but the present disclosure is not limited thereto. In some embodiments of the present disclosure (not shown), in the top view direction Z, the spacer SP1, the spacer SP2 and the spacer SP3 may be, for example, not overlapped with the electrode layer of the corresponding panels. In top view direction Z, the spacer SP1 is, for example, not overlapped with the second electrode layer 15 and/or the first electrode layer 14 of the first panel 1. In the top view direction Z, the spacer SP2 is, for example, not overlapped with the sixth electrode layer 35 and/or the fifth electrode layer 34 of the third panel 3. In the top view direction Z, the spacer SP3 is, for example, not overlapped with the eighth electrode layer 45 and/or the seventh electrode layer 44 of the fourth panel 4. In some embodiments of the present disclosure (not shown), the spacer SP1, the spacer SP2 and the spacer SP3 may, for example, not contact the electrode layer in the corresponding panel. The spacer SP1, for example, does not contact the second electrode layer 15 and/or the first electrode layer 14 in the first panel 1. The spacer SP2, for example, does not contact the sixth electrode layer 35 and/or the fifth electrode layer 34 in the third panel 3. The spacer SP3, for example, does not contact the eighth electrode layer 45 and/or the seventh electrode layer 44 of the fourth panel 4. The plurality of pixel areas PX of the first reflective panel RP1 may be, for example, defined by the follows. For example, the overlapping regions of the second electrode layer 15 and the first electrode layer 14 in the first panel 1 may be defined as the pixel areas PX of the first reflective panel RP1. Similarly, the pixel areas PX of the second reflective panel RP2 (for example, as shown in FIG. 1B) may be defined, for example, by similar ways.

In one embodiment of the present disclosure, even not shown in the figure, the first reflective panel RP1 may be, for example, passive driven, which are not described again here. In the present disclosure, other detail features of the first reflective panel RP1 may be as descried in FIG. 1B, which are not described again here. In addition, other units and materials of the first reflective panel RP1 may be as described above, which are not described again here. In addition, even not shown in the figure, the second reflective panel RP2 (as shown in FIG. 1B) may be active or passive driven, and the detail features may be referred to that of the first reflective panel RP1, which are not described again here.

FIG. 10 is a cross-sectional schematic view of a part of an electronic device according to one embodiment of the present disclosure. The first reflective panel RP1 of FIG. 10 is similar to that of FIG. 9, except for the following differences.

In one embodiment of the present disclosure, as shown in FIG. 10, the first reflective panel RP1 may be, for example, active driven, and the first reflective panel RP1 comprises a first panel 1. More specifically, the first display layer 13 may comprise a first region 131, a second region 132 and a third region 133, the first region 131, the second region 132 and the third region 133 are separated by the spacer SP1. The first electrode layer 14 comprise an electrode 141, an electrode 142 and an electrode 143, the second electrode layer 15 comprises an electrode 151, an electrode 152 and an electrode 153, wherein the electrode 141 and the electrode 151 are used to drive the first region 131 of the first display layer 13, the electrode 142 and the electrode 152 are used to drive the second region 132 of the first display layer 13, and the electrode 143 and the electrode 153 are used to drive the third region 133 of the first display layer 13. The electrode 151, the electrode 152 and the electrode 153 are respectively electrically connected to the transistor TFT1 corresponding thereto, and the transistor TFT1 can transmit signals to the corresponding electrode, thereby driving the first display layer 13 of the corresponding region to achieve the effect of partition display. In the present embodiment, the pixel areas PX of the first reflective panel RP1 may be, for example, defined by the followings. The overlapping region of the electrode 141 and the electrode 151 in the first panel 1 may be defined as a pixel area PX, the overlapping region of the electrode 142 and the electrode 152 may be defined as a pixel area PX, and the overlapping region of the electrode 143 and the electrode 153 may be defined as a pixel area PX. Similarly, the pixel areas PX of the second reflective panel RP2 (for example, as shown in FIG. 1B) may be, for example, defined by similar ways.

In one embodiment of the present disclosure, as shown in FIG. 10, the first panel 1 may further comprise an insulating layer 16 disposed between the first substrate 11 and the first display layer 13. In the top view direction Z, the insulating layer 16 has different thicknesses corresponding to different regions of the first display layer 13. Thus, the first display layer 13 has different thicknesses in the first region 131, the second region 132 and the third region 133. The reflection wavelength and the refractive index of cholesteric liquid crystals is related to the pitch thereof, and the pitch is related to the thickness of the first display layer 13. Thus, by adjusting the thicknesses of the first display layer 13 in the first region 131, the second region 132 and the third region 133, light with different wavelengths is reflected. For example, the first region 131 of the first display layer 13 may reflect red wavelength light, the second region 132 of the first display layer 13 may reflect green wavelength light, and the third region 133 of the first display layer 13 may reflect blue wavelength light, but the present disclosure is not limited thereto. The first region 131 of the first display layer 13, the second region 132 of the first display layer 13 and the third region 133 of the first display layer 13 may reflect light with different wavelengths according to the needs. In one embodiment of the present disclosure, as shown in FIG. 10, in the top view direction Z, the insulating layer 16 has a first thickness T1 in the first region 131 of the first display layer 13, the insulating layer 16 has a second thickness T2 in the second region 132 of the first display layer 13, and the insulating layer 16 has a third thickness T3 in the third region 133 of the first display layer 13. Herein, the first thickness T1 is less than the second thickness T2, and the second thickness T2 is less than the third thickness T3. In the present disclosure, the material of the insulating layer 16 may comprise silicon nitride, silicon oxide, silicon oxynitride, silicon carbonitride, aluminum oxide, organic materials, or a combination thereof, but the present disclosure is not limited thereto.

In one embodiment of the present disclosure, even not shown in the figure, the first reflective panel RP1 may be, for example, passive driven, which are not described again here. In the present disclosure, other detail features of the first reflective panel RP1 may be as described in FIG. 9, which are not described again here. In addition, other units and materials of the first reflective panel RP1 may also be as described above, which are not described again here. In addition, even not shown in the figure, the second reflective panel RP2 (as shown in FIG. 1B) may be active or passive driven, and other detail features can be referred to that of the first reflective panel RP1, which are not described again here.

In the present disclosure, the first reflective panel RP1 and the second reflective panel RP2 are assembled. By designing the display direction of the first reflective panel RP1 to be different from the display direction of the second reflective panel RP2, the double-sided display effect of the electronic device can be achieved. In addition, by disposing the photoelectric conversion unit E1 in the electronic device, at least part of the incident light that is not reflected by the display layer can be absorbed, and converted into electrical energy to provide to the first reflective panel RP1 and the second reflective panel RP2 respectively, thereby achieving the effect of power saving or improving the color purity of reflected light. Therefore, the electronic device disclosed herein can be applied to electronic devices that require double-sided display, such as billboards on highways or sidewalks or bus stops. In addition, when the electronic device of the present disclosure is switched to a single-sided display, the side that does not display images can increase the amount of incident light entering the photoelectric conversion unit, thereby enhancing the photoelectric conversion effect.

The above specific embodiments should be construed as merely illustrative and not limitative of the remainder of the disclosure in any way.

1. An electronic device, comprising:
a first reflective panel having a first display side and comprising a first display layer;
a second reflective panel having a second display side and comprising a second display layer; and
a photoelectric conversion unit disposed between the first display layer and the second display layer, wherein the photoelectric conversion unit is used to receive external light and convert the external light into electrical energy to provide the electrical energy to the first reflective panel and the second reflective panel,
wherein the first display side and the second display side face different directions respectively.

2. The electronic device of claim 1, wherein the photoelectric conversion unit is disposed between the first reflective panel and the second reflective panel.

3. The electronic device of claim 1, wherein the photoelectric conversion unit is disposed in one of the first reflective panel and the second reflective panel.

4. The electronic device of claim 1, wherein the photoelectric conversion unit comprises a first photoelectric conversion unit and a second photoelectric conversion unit adjacent thereto, the first photoelectric conversion unit comprises a first photoconversion layer and two electrodes disposed on two sides of the first photoconversion layer, wherein one of the two electrodes of the first photoelectric conversion unit adjacent to the second photoelectric conversion unit is a non-transparent conductive layer.

5. The electronic device of claim 4, wherein the first photoelectric conversion unit and the second photoelectric conversion unit respectively are a perovskite solar cell.

6. The electronic device of claim 4, wherein the non-transparent conductive layer comprises a metal material.

7. The electronic device of claim 4, wherein the first reflective panel comprises a first panel, and the first panel comprises a first substrate and a second substrate opposite to the first substrate, wherein the first photoelectric conversion unit comprises a substrate disposed opposite to the second substrate, the first photoconversion layer is disposed between the substrate and the second substrate, the one of the two electrodes is disposed between the substrate and the first photoconversion layer, and the other one of the two electrodes is disposed between the second substrate and the first photoconversion layer.

8. The electronic device of claim 4, wherein the second photoelectric conversion unit comprises a second photoconversion layer and two electrodes disposed on two sides of the second photoconversion layer, wherein one of the two electrodes of the second photoelectric conversion unit adjacent to the first photoelectric conversion unit is a non-transparent conductive layer.

9. The electronic device of claim 8, wherein the non-transparent conductive layer comprises a metal material.

10. The electronic device of claim 8, wherein the second reflective panel comprises a second panel, and the second panel comprises a third substrate and a fourth substrate opposite to the third substrate, wherein the second photoelectric conversion unit comprises a substrate disposed opposite to the fourth substrate, the second photoconversion layer is disposed between the substrate and the fourth substrate, the one of the two electrodes is disposed between the substrate and the second photoconversion layer, and the other one of the two electrodes is disposed between the fourth substrate and the second photoconversion layer.

11. The electronic device of claim 4, further comprising an adhesive layer disposed between the first photoelectric conversion unit and the second photoelectric conversion unit, wherein the adhesive layer comprises a non-transparent material.

12. The electronic device of claim 1, further comprising:
a first protective substrate disposed on a side of the first reflective panel away from the second reflective panel, wherein the first protective substrate has a first active region and a first peripheral region, the first active region is a region overlapping a plurality of pixel areas of the first reflective panel, and the first peripheral region is a region of the first protective substrate excluding the first active region; and
a second photoelectric conversion unit disposed in the first peripheral region of the first protective substrate.

13. The electronic device of claim 12, further comprising:
a second protective substrate disposed on a side of the second reflective panel away from the first reflective panel, wherein the second protective substrate has a second active region and a second peripheral region, the second active region is a region overlapping a plurality of pixel areas of the second reflective panel, and the second peripheral region is a region of the second protective substrate excluding the second active region; and
a third photoelectric conversion unit disposed in the second peripheral region of the second protective substrate.

14. The electronic device of claim 1, further comprising:
a first light guide element disposed on a side of the first reflective panel away from the second reflective panel; and
a first light source disposed adjacent to the first light guide element,
wherein the photoelectric conversion unit is further used to provide the electrical energy to the first light source.

15. The electronic device of claim 14, further comprising:
a second light guide element disposed on a side of the second reflective panel away from the first reflective panel; and
a second light source disposed adjacent to the second light guide element,
wherein the photoelectric conversion unit is used to provide the electrical energy to the second light source.

16. The electronic device of claim 1, wherein the photoelectric conversion unit is a perovskite solar cell.

17. The electronic device of claim 1, further comprising an energy storage device electrically connected to the photoelectric conversion unit.

18. The electronic device of claim 1, wherein the photoelectric conversion unit comprises a first photoelectric conversion unit and a second photoelectric conversion unit adjacent thereto, the first photoelectric conversion unit is disposed in the first reflective panel, and the second photoelectric conversion unit is disposed in the second reflective panel.

19. The electronic device of claim 18, wherein the first photoelectric conversion unit and the second photoelectric conversion unit respectively are a perovskite solar cell.

20. The electronic device of claim 1, wherein the first display layer and the second display layer respectively comprise cholesteric liquid crystals.
